(19) United States
(12) Patent Application Publication
(10) Pub. No.: US 2009/0199896 A1
(43) Pub. Date: Aug. 13, 2009

(54) Dye-sensitized solar cell

(75) Inventors: Hirokazu Fujimaki, Miyazaki (JP); Hidehiro Higashino, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/320,045

(22) Filed: Jan. 15, 2009

(30) Foreign Application Priority Data
Jan. 16, 2008 (JP) 2008-006461

(51) Int. Cl. H01L 31/0224

(52) U.S. Cl. 136/252; 257/E31.124

(57) ABSTRACT

According to the present invention, a dye-sensitized solar cell includes a conductive substrate, which is transparent; and a photovoltaic (photoelectric exchange) layer formed on the conductive substrate. The photovoltaic layer comprises a lighter (brighter) region and a darker region therein.

### CROSS REFERENCE TO RELATED APPLICATION

This application claims the priority of Application No. 2008-006461, filed Jan. 16, 2008 in Japan, the subject matter of which is incorporated herein by reference.

### TECHNICAL FIELD OF THE INVENTION

The present invention relates to a dye-sensitized solar cell, in particular, light transmission characteristics and reflection characteristics are well controlled.

### BACKGROUND OF THE INVENTION

Currently, as a solar cell, a silicon system solar cell is main stream. According to a silicon system solar cell, it is required to manufacture it in a high temperature and high vacuum condition with large equipment. Further, according a silicon system solar cell, since high purity silicon is used for manufacturing, manufacturing costs would be high. On the other hand, a dye-sensitized solar cell can be used under condition of atmosphere pressure and lower temperature, and low-cost material can be used for fabrication. As a result, as compared with a silicon system solar cell, such a dye-sensitized solar cell can be manufactured with lower costs.

In addition, as compared with a silicon solar cell, a dye-sensitized solar cell can be fabricated with a variety of colors, and a lighter weight, flexibility, and is improved in design.

Such a dye-sensitized solar cell has been improved and expected as a future solar cell, especially in a field of an electric device, which is required to be small in size and lower power consumption. If a dye-sensitized solar cell is realized for a main battery or an auxiliary battery in an electric device, power charging would not be necessary or frequency of power charging would be decreased. Further, since an electric device is often used for a personal use of individuals, a design is important. A dye-sensitized solar cell is sophisticated in design, so that a dye-sensitized solar cell could be used in a wider production field.

Patent Publication 1 describes a thin solar cell module is provided with a photovoltaic layer having a three-layer structure, including a p-type amorphous silicon carbide layer, an i-type amorphous silicon layer and an n-type amorphous silicon layer. The photovoltaic layer is divided into strip shape regions to form specific letters, symbols and patterns.

### [Patent Publication 1] JP 2002-343998A

However, the solar cell described in Patent Publication 1 is of a thin film solar cell module but does not describe light transmission characteristics and reflection characteristics are changed selectively in region.

According to Patent Publication 1, letters, symbols or patterns are formed by digging out a part of a photovoltaic layer (amorphous silicon layer). Therefore, if the technology shown in Patent Publication 1 is applied to a dye-sensitized solar cell, a titania layer, which is a photovoltaic layer, would be partly removed, as a result efficiency of photoelectric exchange would be lowered.

### OBJECTS OF THE INVENTION

Accordingly, an object of the present invention is to provide a dye-sensitized solar cell, in which desired letters, shapes and images can be formed without lowering efficiency of photoelectric exchange.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a dye-sensitized solar cell includes a conductive substrate, which is transparent; and a photovoltaic (photoelectric exchange) layer formed on the conductive substrate. The photovoltaic layer comprises a lighter (brighter) region and a darker region therein.

According to a second aspect of the present invention, a method for fabricating a dye-sensitized solar cell includes the steps of: coating a conductive material on a transparent conductive substrate; forming a first photovoltaic layer on the conductive substrate; and forming a second photovoltaic layer on the first photovoltaic layer. The first and second photovoltaic layers are formed by a plurality of screen printing steps using a plurality of masks having different patterns so as to provide differences in color and/or brightness.

According to a third aspect of the present invention, a method for fabricating a dye-sensitized solar cell includes the steps of: coating a conductive material on a transparent conductive substrate; forming a plurality of collector electrodes on the conductive substrate; and forming a photovoltaic layer on the conductive substrate. The collector electrodes are arranged to have a space between next two electrodes, which are different from region to region so as to provide differences in color and/or brightness.

According to a fourth aspect of the present invention, a method for fabricating a dye-sensitized solar cell includes the steps of: coating a conductive material on a transparent conductive substrate; forming a plurality of collector electrodes on the conductive substrate; and forming a photovoltaic layer on the conductive substrate. The collector electrodes are shaped to have a surface area, which is different from region to region so as to provide differences in color and/or brightness.

According to a fifth aspect of the present invention, a method for fabricating a dye-sensitized solar cell includes the steps of: coating a conductive material on a transparent conductive substrate; forming a plurality of collector electrodes on the conductive substrate; and forming a photovoltaic layer on the conductive substrate. The collector electrodes are formed to have a surface area and to have a space between next two electrodes, which is different from region to region so as to provide differences in color and/or brightness.

As described above, according to the present invention, a photovoltaic layer (titania layer) has a thicker region and a thinner region, so that it could be easy to form letters, designs and patterns based on differences in transmissivity of light without lowering photovoltaic efficiency. Photovoltaic is carried out both in the thicker region and thinner region on the photovoltaic layer.

### BRIEF DESCRIPTION OF THE DRAWINGS

FIGS. 1A-1D are plane views showing a part of fabrication process of a dye-sensitized solar cell according to a first preferred embodiment of the present invention.

FIGS. 2A-2D are plane views showing a part of fabrication process of a dye-sensitized solar cell according to a second preferred embodiment of the present invention.

FIGS. 3A and 3B are enlarged plane views illustrating a part of pattern shown in FIG. 2D.

FIGS. 4A-4C are plane view showing a part of fabrication process of a dye-sensitized solar cell according to a third preferred embodiment of the present invention.

FIG. 5 is an explanatory drawing showing a structure of the dye-sensitized solar cell shown in FIG. 4C.

FIG. 6 is an alternative embodiment of the dye-sensitized solar cell shown in FIGS. 4C and 5.

### DESCRIPTION OF REFERENCE NUMERALS

101, 201, 301: Glass Substrate
102″, 103′, 202″,203′, 314, 316: Photovoltaic Region
310, 410: Collector Electrode

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

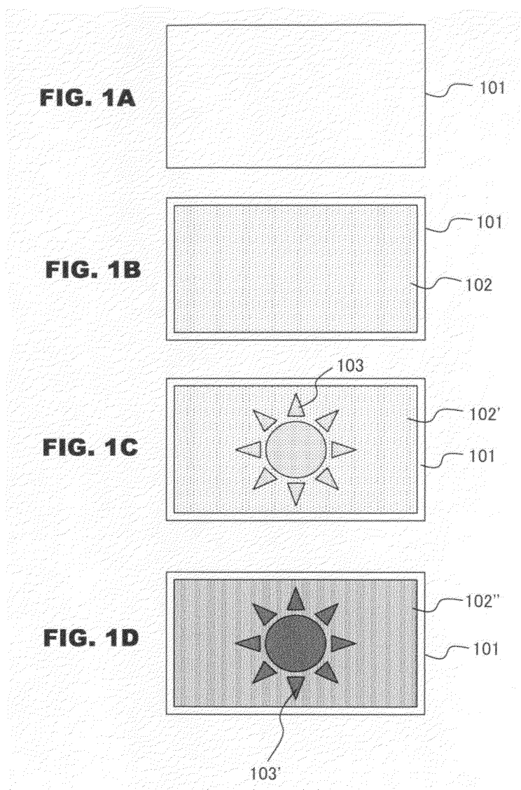

FIGS. 1A-1D are plane views showing a part of fabrication process of a dye-sensitized solar cell according to a first preferred embodiment of the present invention. First, as shown in FIG. 1A, a base plate (substrate) 101, which is of a glass plate or a film material having a surface coated with a conductive layer of FTO (Fluorine-doped Tin Oxide) or ITO (Indium-Tin Oxide), is prepared. The conductive layer coated over the base plate 101 has a sheet resistance of 10 ohms/□ (square) and has a thickness of about 0.5 um. Such a conductive layer may be of a conductive PET film or the like.

Next, as shown in FIG. 1B, a paste material 102 is coated on the substrate 101 entirely to have a thickness of about 50 um by a screen printing process or a coating process. The paste layer 102 includes fine grains of TiO2, having diameters of 10-50 um. If the substrate is made of glass plate, HT/SP, H/SP, D/SP produced by Solaronix Co. Ltd. could be employed as the paste layer 102. On the other hand, if the substrate 101 is made of a film material, an titanium oxide paste for low-temperature formation (for example, PECC-KO1 produced by Peccell Technologies, Inc., etc.) could be used. The paste layer 102 is formed to have a thickness of about 20 um in a wet condition after screen printing process.

After that, if a glass substrate is used as the base plate, a burning process would be carried out for about one hour in atmospheric air at a temperature of 450 degrees C. Alternatively, a drying process would be carried out for 30 minutes at a temperature of 120 degrees C. in stead. On the other hand, if the substrate 101 is made of a film material, a burning process or a drying process would be carried out for 30 minutes at a temperature of 120 degrees C.

Next, a second screen printing process is carried out using a mask pattern (103), which is different from that used for the first screen printing process. The same titanium oxide paste can be used but can be changed. If a glass plate is used as the base plate 101, “300/SP” produced by Solaronix Inc. could be used only for the second screen printing process. After that, a burning process is carried out for about an hour at a temperature of 450 degrees C. As shown in FIG. 1C, the titanium oxide layer formed on the base plate 101 has regions (102′ and 103) having the different thicknesses.

According to the present embodiment, a whole surface pattern is used for the first printing process, while a desired specific pattern (sun shape) is used for the second printing process. Those patterns used for the first and second patterns can be change to each other. When a whole surface pattern is used for the second printing process, the outline of a specific pattern formed in the first printing process could become unclear.

Next, the substrate is dipped into an alcoholic solution, including Ru metal complex dye (N719), for six hours at a temperature of 50 degrees C., as shown in FIG. 1D. Ru metal complex dye is adhered to a surface of porous titanium oxide layer at a high density. Optical absorption is different between a region 103′, on which a titanium oxide layer is screen-printed twice, and a region 102″, on which a titanium oxide layer is screen-printed once. As a result, variation of darkness of color is formed between the regions 103′ and 102″. Here, screen printing process can be carried out three times or more. Further, printing patterns can be prepared three or more. Variation of darkness of color can be formed on a single substrate.

After that the substrate is ethanol-washed and dried in a dark place. Next, another substrate (not shown) having pin holes of 1 mm or less of diameter is prepared, in which a conductive layer and a thin Pt layer are formed on a surface in a sputtering process. The conductive layer and thin Pt layer are to be a counter electrode of the solar cell. On the other hand, a HIMILAN film (Mitsui/Dupon Chemical: 1004) is formed around the TiO2 electrode plate (101). Those two electrode plates are adhered to each other at a temperature of 130 degrees C. Next, electrolyte including iodine is poured from the pin holes of the electrode plate so that the gap (space) between the two electrode plates is filled with the electrolyte. Subsequently, the pin holes are covered and closed. After that, a minus electrode wiring is connected to the Titania electrode, while a plus electrode wiring is connected to the counter electrode to form a dye-sensitized solar cell in flat shape.

In operation, when a light shines into the Titania electrode, dyes adhered on the surface of the Titania electrode absorbs the light and electrons are excited therefrom. The excited electrons are transferred toward the Titania layer. Further, the electrons travel through the conductive layer on the glass plate to drive external load and reach the anode side. After that, the electrons are supplied in the electrolyte due to reductive reaction with iodine ions. Next, a oxidation reaction occurs to transfer the electrons to the dyes. This operation (phenomenon) is repeated to generate photoelectromotive force based on a steady photoirradiation.

As described above, according to the first preferred embodiment, a plurality of regions having different brightness on a single substrate, so that it could be easy to form letters, designs and patterns, which seem like rising to the surface of the solar cell. Also, a continuing pattern having different lightness and darkness of color can be formed, so that design performance of a solar cell would be improved. According to the present embodiment, not only a digital type of pattern having on or off regions, but also an analog type of pattern having gradation of lightness and darkness of color can be formed. According to the present invention, bright regions also include titanium oxide, on which dyes are adhered, so that such bright regions could function to generate electrical energy.

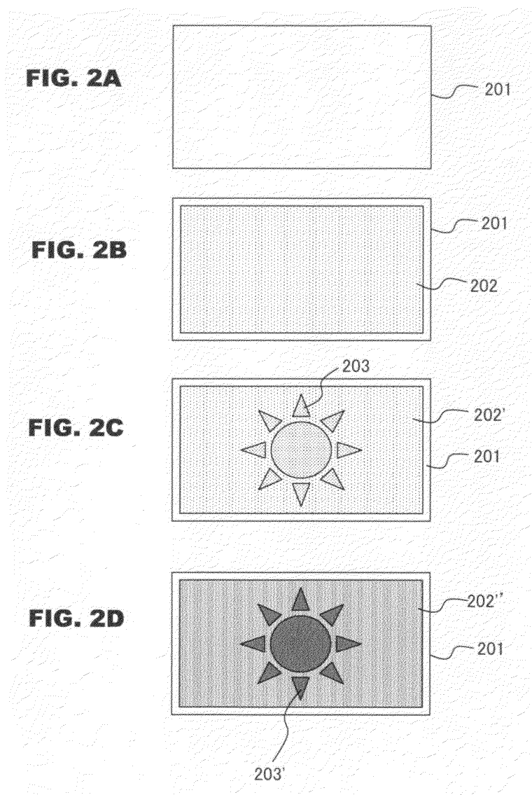

FIGS. 2A-2D are plane views showing a part of fabrication process of a dye-sensitized solar cell according to a second preferred embodiment of the present invention. First, as shown in FIG. 2A, a base plate (substrate) 201, which is of a glass plate or a film material having a surface coated with a conductive layer of FTO (Fluorine-doped Tin Oxide) or ITO (Indium-Tin Oxide), is prepared. The conductive layer coated over the base plate 201 has a sheet resistance of 10 ohms/□ (square) or less and has a thickness of about 0.5 um. Such a conductive layer may be of a conductive PET film (for example, OTEC produced by Tohbi Inc.) or the like.

Next, as shown in FIG. 2B, a paste material 202 is coated on the substrate 201 entirely to have a thickness of about 50 um by a screen printing process or a coating process. The paste layer 202 includes fine grains of TiO2, having diameters of 10-50 um. If the substrate 201 is made of glass plate, HT/SP, H/SP, D/SP produced by Solaronix Co. Ltd. could be employed as the paste layer 202. On the other hand, if the substrate 201 is made of a film material, an titanium oxide paste for low-temperature formation (for example, PECC-KO1 produced by Peccell Technologies, Inc., etc.) could be used. The paste layer 202 is formed to have a thickness of about 20 um in a wet condition after screen printing process.

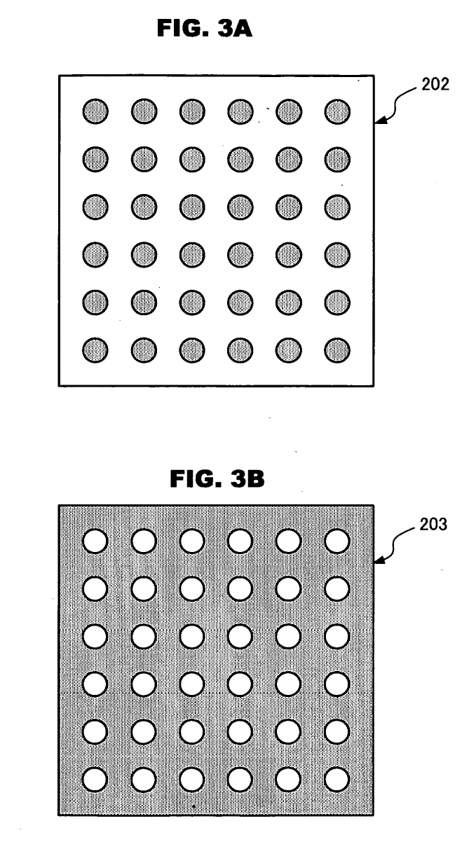

According to the present embodiment, a screen pattern used for the first screen printing process is not a whole surface pattern, but is a pattern with dots 202, as shown in FIG. 3A, a grid-like pattern or the like. As a result, light transmittance could be determined to be different from region to region. In this case, only doted-pattern may be printed, or only doted-pattern may not be printed.

After that, if a glass substrate is used as the base plate 201, a burning process would be carried out for about one hour in atmospheric air at a temperature of 450 degrees C. to perform a necking of titanium oxide. On the other hand, if the substrate 201 is made of a film material, a burning process or a drying process would be carried out for 30 minutes at a temperature of 120 degrees C.

Next, a second screen printing process is carried out using a mask pattern (sun shape), which is different from that used for the first screen printing process. The same titanium oxide paste can be used but can be changed. If a glass plate is used as the base plate 201, “300/SP” produced by Solaronix Inc. could be used only for the second screen printing process. After that, if a glass plate is used as the base plate 201, a burning process would be carried out for about an hour at a temperature of 450 degrees C. If a film material is used as the base plate 201, a burning process would be carried out for about 30 minutes at a temperature of 120 degrees C. As shown in FIG. 2C, the titanium oxide layer formed on the base plate 101 has regions (202′ and 203) having the different thicknesses.

According to the present embodiment, a whole surface pattern is used for the first printing process, while a desired specific pattern (sun shape) is used for the second printing process. The screen pattern used for the second printing process, may be a pattern with dots 203, as shown in FIG. 3B, a grid-like pattern or the like. As a result, light transmittance could be determined to be different from region to region, which could be, for example, a square of 1 cm*1 cm or less.

Next, the substrate is dipped into an alcoholic solution, including Ru metal complex dye (N719), for six hours at a temperature of 50 degrees C., as shown in FIG. 2D. Ru metal complex dye is adhered to a surface of porous titanium oxide layer at a high density. Optical absorption is different between a region 203′, on which a titanium oxide layer is screen-printed twice, and a region 202″, on which a titanium oxide layer is screen-printed once. As a result, variation of darkness of color is formed between the regions 203′ and 202″. Here, screen printing process can be carried out three times or more. Further, printing patterns can be prepared three or more. Variation of darkness of color can be formed on a single substrate.

As described above, according to the present embodiment, a plurality of regions having optical absorption rates, so that different brightness can be formed on a single substrate. The first and second embodiments may be combined to each other. For example, a whole surface pattern is formed in a first screen printing process, and titanium oxide regions, having a local pattern ration of one or less, may be formed on the whole surface pattern.

According to the second preferred embodiment, a plurality of variety of patterns, in which brightness and darkness are changed continuously, may be formed on a single substrate. By controlling pattern ratios, dot size, line-and-space of grid pattern, a variety of tone of color can be expressed.

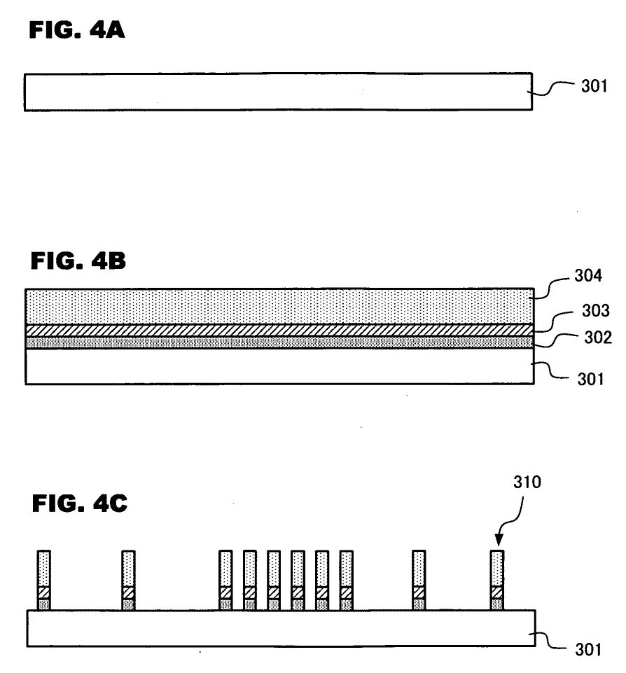

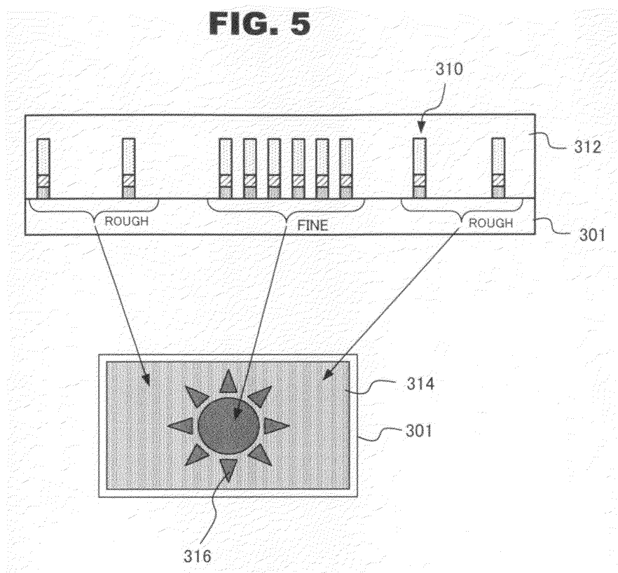

FIGS. 4A-4C are plane view showing a part of fabrication process of a dye-sensitized solar cell according to a third preferred embodiment of the present invention. FIG. 5 is an explanatory drawing showing a structure of the dye-sensitized solar cell shown in FIG. 4C. According to the third preferred embodiment, a density (roughness and fineness) of a collector electrode pattern is changed region to region.

In fabrication, first, a TiN layer 302 is formed on a glass substrate 301 to have a thickness of 500 angstroms by a sputtering process. Next, a Ti layer 303 is formed on the TiN layer 302 to have a thickness of 200 angstroms by a sputtering process. Subsequently, a W layer 304 is formed on the Ti Layer 303 to have a thickness of 1 um, as shown in FIG. 4B. After that, a photolithography process and an etching process are carried out to expose a part of the glass substrate to form collector electrode 310, as shown in FIG. 4C. For example, a line width of the electrode 310 may be about 2 um in the patterning process. From a plan view, the collector electrode 310 is shaped to be grid pattern, a honeycomb pattern or the like, and is electrically connected.

According to the present embodiment, a space between next two collector electrode portions 310 (density, roughness and fineness) is varied to form crowded regions and rough regions. For the collector electrode pattern 310, a variety of patterns can be employed.

After that, a Ti layer is formed in conformal to have a thickness of about 100 angstroms as a barrier layer against reverse electrons. In stead of forming the Ti layer, a FTO layer or ITO layer having a thickness of 1 um may be formed by a CVD process or spraying process.

A titanium oxide paste is formed entirely on the substrate to have a thickness of about 50 um by a screen printing process. After that, a burning process is carried out for about one hour at a temperature of 450 degrees C. The following steps are the same as those for the first and second preferred embodiment, and the same description is not repeated here.

A feature of the present embodiment is that a space between next two collector electrode patterns 310 is controlled to form rough regions of electrode and fineness regions of electrode. In a region where the collector electrode patterns 310 are roughly arranged, a pattern ratio (area ratio) of titanium oxide layer, on which dyes are adhered, is high. On the other hand, in a region where the collector electrode patterns 310 are finely arranged (high density), a pattern ratio (area ratio) of titanium oxide layer, on which dyes are adhered, is low. As a result, a color tone of the solar cell can be modified easily by controlling the spaces (gaps or distances) of the collector electrode patterns 310.

According to the present invention, as compared with the first and second preferred embodiment, the most appropriate condition (layer thickness, particle diameter) of the titanium oxide layer 312 can be used, and a collector electrode is provided, so that a high performance solar cell with a lower internal series resistance can be obtained. Further, a color tone and any other design of the solar cell can be changed independently by controlling the roughness and fineness of the collector electrodes.

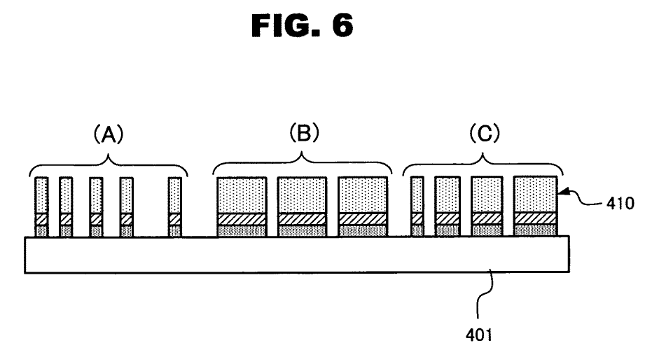

FIG. 6 is an alternative embodiment of the dye-sensitized solar cell shown in FIGS. 4C and 5. The fundamental structure of a solar cell shown in FIG. 6 is the same as that of the third preferred embodiment. However, according to the third preferred embodiment, the collector electrodes 310 are formed to have the same (uniform) width. On the other hand, according to the present embodiment shown in FIG. 6, a line width (surface area) of collector electrodes 410, formed on a glass substrate 401, is changed as shown in (B); or a space between next two collector electrodes 410 is changed continuously or discontinuously, as shown in (A); or the both a line width (surface area) and a space of the collector electrodes are changed continuously or discontinuously.

According to the embodiment shown in FIG. 6, in addition to the third preferred embodiment, more variety of color tone and gradation can be realized. Color tone in bottleneck regions of a solar cell can be controlled by adjusting a width and space of the collector electrodes 410, so that color continuity could be maintained while keeping resistance at the bottleneck regions low.

What is claimed is:

1. A dye-sensitized solar cell, comprising:
a conductive substrate, which is transparent; and
a photovoltaic (photoelectric exchange) layer formed on the conductive substrate, wherein
the photovoltaic layer comprises a lighter (brighter) region and a darker region.

2. A dye-sensitized solar cell according to claim 1, wherein
the lighter region and darker region have the different thickness of the photovoltaic layer, so that light transmission and reflection characteristics can be controlled region to region.

3. A dye-sensitized solar cell according to claim 2, wherein
the photovoltaic layer is formed by a plurality of screen printing or coating steps using a plurality of masks, having different patterns.

4. A dye-sensitized solar cell according to claim 3, wherein
at least one step of the screen printing or coating is a whole surface printing or coating.

5. A dye-sensitized solar cell according to claim 3, wherein
at least one step of the screen printing or coating is carried out so that the photovoltaic layer has regions with different local pattern ratios (area ratio or density).

6. A dye-sensitized solar cell according to claim 2, further comprising:
a plurality of collector electrodes, patterned on the conductive substrate, wherein
the plurality of collector electrodes are formed to have different space between next two electrodes for each region so that the photovoltaic layer has different thickness for each region.

7. A dye-sensitized solar cell according to claim 2, further comprising:
a plurality of collector electrodes, patterned on the conductive substrate, wherein
the plurality of collector electrodes are formed to have a different surface area for each region so that the photovoltaic layer has different thickness for each region.

8. A dye-sensitized solar cell according to claim 2, further comprising:
a plurality of collector electrodes, patterned on the conductive substrate, wherein
the plurality of collector electrodes are formed to have different space between next two electrodes and a different surface area for each region so that the photovoltaic layer has different thickness for each region.

9. A dye-sensitized solar cell according to claim 8, wherein
the collector electrodes are made of a metal including at least one of W, Ag and Cu.
